(19) United States
(12) Patent Application Publication
(10) Pub. No.: US 2026/0040507 A1
(43) Pub. Date: Feb. 5, 2026

(54) INVERTER WITH BUS BAR COOLING SYSTEM

(71) Applicant: DANA TM4 INC., Boucherville (CA)

(72) Inventors: Mohammad AMAR, Montreal (CA); Michel BRAZEAU, Delson (CA); Francois DUBE, Montreal (CA); Maalainine EL YACOUBI, Sainte Julie (CA); Marc-Antoine BEAUPRÉ, Mont-Saint-Hilaire (CA)

(21) Appl. No.: 18/794,513

(22) Filed: Aug. 5, 2024

(51) Int. Cl. H05K 7/20; H02M 7/00

(52) U.S. Cl. CPC H05K 7/209; H02M 7/003

(57) ABSTRACT

Systems are herein provided for an inverter with a direct current (DC) bus bar cooling system. In one example, an inverter comprises a case, a DC bus bar positioned within the case and electrically isolated from the case, a first compressible thermal pad positioned on a first flat surface of the DC bus bar proximate to a DC input connector, and a second compressible thermal pad positioned on a second flat surface of the DC bus bar opposite the first flat surface. Each of the first and second compressible thermal pads are in thermal contact with a section of a housing of the inverter.

### TECHNICAL FIELD

Embodiments of the subject matter disclosed herein relate to inverters, and more particularly to a cooling system for a bus bar of an inverter.

### BACKGROUND AND SUMMARY

Inverters are used in a variety of fields to change direct current (DC) to alternating current (AC). Inverters are used in a variety of fields such as electric vehicles, solar installations, industrial equipment, etc. Inverters are power modules that switch at high frequency to enable the DC to AC conversion. Inverters comprise a DC bus input, which includes one double or two single connects, two bus bars (one positive and one negative), and an electromagnetic interference (EMI) filter. DC power required by the inverter passes through the DC bus input. As the DC can be very high, it generates large amounts of heat.

To reduce the heat generated by conduction losses in bus bars and connects a most common approach is to oversize the bus bars and connectors to reduce electrical resistance, thus reducing heating of the bus bars and connects. However, increasing the size of the bus bars and the connectors increases the overall footprint of the inverter.

The inventors herein have recognized the aforementioned issues and developed a bus bar cooling system for an inverter assembly that at least partially addresses these issues. The inverter assembly includes, in one example, a case, a DC bus bar positioned within the case and electrically isolated from the case, a first compressible thermal pad positioned on a first flat surface of the DC bus bar proximate to a DC input connector, and a second compressible thermal pad positioned on a second flat surface of the DC bus bar opposite the first flat surface.

The DC bus bar may thus be positioned between and in thermal contact with the first and second thermal pads, which may further be in thermal contact with a first and second section of the case, respectively. The thermal pads may thus electrically isolate the DC bus bar from the case while allowing for thermal exchange with the case. The DC bus bar may be positioned between the two thermal pads in order to increase the amount of heat exchange and thereby decrease the amount of heat through the DC bus bar.

Further, the first and second compressible thermal pads may be formed of a compressible material, such as spongy material. Thus, the thermal pads may compress and form different thicknesses between other components of the inverter 100. In this way, the necessary preciseness of forming the thermal pads and other components may be reduced, providing for an easier manufacturing process.

It should be understood that the brief description above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 shows an illustration of an inverter and an exemplary operating environment in which it may be utilized.

FIG. 2 shows a cross-sectional view of the inverter of FIG. 1, with the cross-section extending through multiple chambers in the housing.

FIG. 3 shows a cross-sectional view of the inverter of FIG. 1, with the cross-section extending through a direct current (DC) assembly.

FIG. 4 shows a detailed perspective view of the DC bus bar assembly in the inverter of FIG. 1.

FIG. 5 shows a cross-sectional view of the inverter of FIG. 1, with the cross section extending through the DC bus bar.

FIG. 6 shows an exploded view of the DC bus bar assembly in the inverter of FIG. 1.

FIG. 7 shows a detailed perspective view of the inverter of FIG. 1.

FIG. 8 shows another cross-sectional view of the inverter of FIG. 1.

### DETAILED DESCRIPTION

The following description relates to systems for a bus bar cooling system of an inverter assembly that reduces heat in a direct current (DC) bus bar assembly. The inverter assembly described herein includes the DC bus bar that is electrically isolated from a case of the inverter. The DC bus bar is positioned between two compressible thermal pads, a first being positioned on a first flat surface of the DC bus bar proximate to a DC input connector and a second being positioned on an opposing second flat surface of the DC bus bar. Each of the thermal pads are in contact with a heat exchanger that is in contact with the case, the heat exchangers are configured to transfer heat away from the thermal pads and DC bus bar.

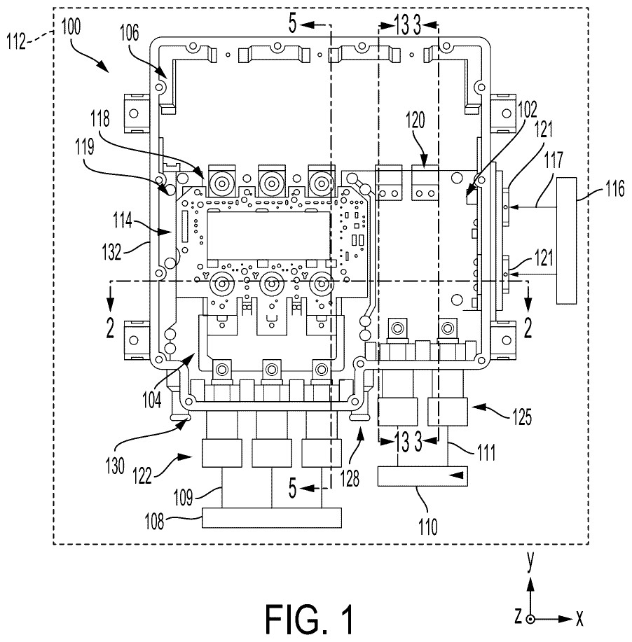

FIG. 1 depicts an inverter 100 that is designed to convert DC to alternating current (AC). To achieve this functionality, the inverter 100 includes a DC bus bar assembly 102 and an AC bus bar assembly 104 which are both electrically connected to a DC link capacitor 106 either directly or indirectly. To form the internal electric connections in the inverter described herein conductive plates, harnesses, capacitors, cables, combinations thereof, and the like may be used to establish these connections. Similarly, cables, harnesses, combinations thereof, and/or other suitable components for establishing electrical connections may be used to electrically couple the inverter to external components. However, cables, under some operating conditions, may function as antennas which pick up electromagnetic interference (EMI) noise. Therefore, use of extraneous cables within the inverter may be reduced (e.g., avoided) to diminish internal EMI.

The inverter 100 may be coupled to an AC electrical component 108 and a DC electrical component 110 (e.g., a vehicle energy storage system, in an electric vehicle (EV) embodiment). Cables 109 and 111 and/or other suitable electrically conductive components may be used to electrically couple the AC electrical component 108 and the DC electrical component 110 to the inverter 100. In one example, the inverter 100 may be included in an EV 112 or other suitable electric system, and may be referred to as a power electronics unit, in the EV example. In such an example, the inverter adjust the speed of a traction motor in the vehicle. The EV 112 may be a light, medium, or heavy duty vehicle. In such an example, the AC electrical component 108 may be a traction motor and the DC electrical component 110 may be a traction battery. However, it will be understood that the inverter may be included in a variety of environments. For example, the inverter 100 may be included in a solar power installation, an industrial machine, and the like.

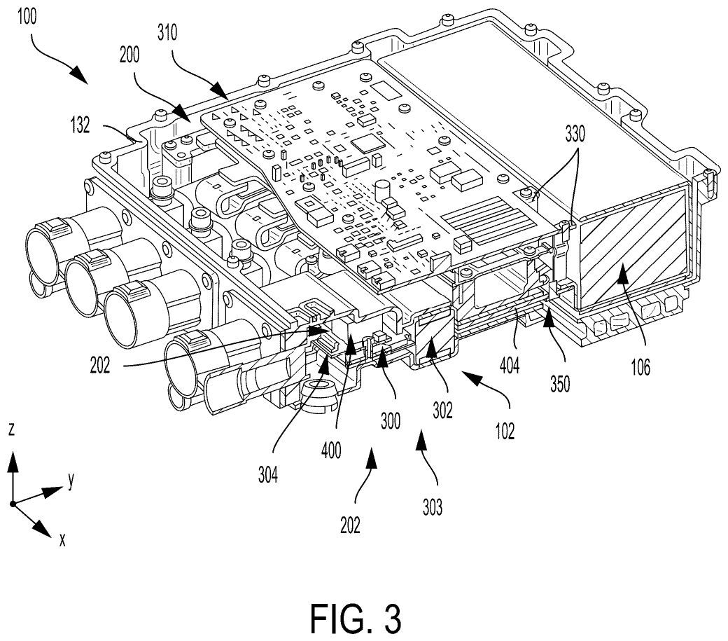

Further, the inverter 100 may include a gate-driver circuit board (e.g., a gate-driver printed circuit board assembly (PCBA)) 114 that is designed to control the power distributed by the inverter 100. For instance, in the EV example, the gate-driver circuit board 114 adjusts the amount of power supplied to the traction motor to alter the motor's speed. However, as indicated above, the inverter 100 may be used in a variety of operating environments. The gate-driver circuit board 114 and the other circuit boards described herein may include one or more microprocessors, memory, and the like to achieve the power adjustment functionality. A control circuit board 310 (e.g., the control PCBA), shown in FIG. 3, may receive electrical energy and receive signals from and send signals to a lower voltage component 116 as indicated via arrows 117. To elaborate, electrical connectors 121 that form an external communication interface serve as the connection between the lower voltage component 116 and a flexible circuit board which is electrically connected to the control circuit board 310, shown in FIG. 3 and discussed in greater detail herein. The lower voltage component may include a lower voltage power supply and/or a controller. As such, this electrical energy may have a lower voltage than the electrical energy flowing into and out of the inverter via the connectors 122 and 125.

As illustrated in FIG. 1, the DC link capacitor 106 is electrically coupled to a power module 119 (e.g., a power transistor module) via an electrical interface 118 (e.g., a DC bus bar interface). The electrical interface 120 between the DC bus bar assembly 102 and the DC link capacitor 106 is further depicted. Further, electrical connectors 122 that facilitate efficient electrical coupling between phase bus bars in the AC bus bar assembly 104 and the AC electrical component 108 is additionally illustrated in FIG. 1. DC input connectors 125 that facilitate efficient electrical coupling between DC bus bars in the DC bus bar assembly 102 and the DC electrical component 110 (e.g., the vehicle's energy storage system, as indicated above) are further illustrated in FIG. 1. However, other arrangements of the power module and the DC link capacitor have been contemplated.

In the illustrated example, a coolant inlet 128 and a coolant outlet 130 are further included in the inverter 100. A housing 132 (e.g., a case) may include coolant conduits through which the coolant circulates may be hydraulically coupled to the coolant inlet and outlet such as one or more pumps, a heat exchanger, a filter, and the like. The coolant may include water, glycol, combinations thereof, and the like. However, the cooling system may have a different configuration or be omitted, in other examples.

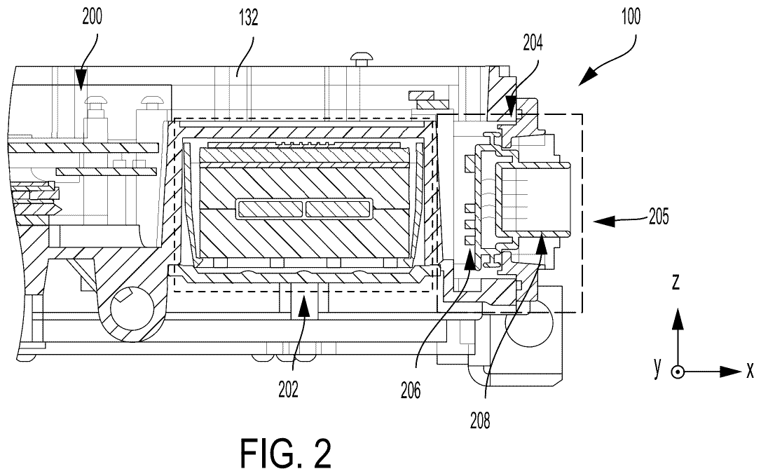

An axis system is provided in FIG. 1 as well as FIGS. 2-8, for reference. The z-axis may be a vertical axis (e.g., parallel to a gravitational axis), the x-axis may be a lateral axis (e.g., horizontal axis), and/or the y-axis may be a longitudinal axis, in one example. However, the axes may have other orientations in other examples. Cutting planes 2-2, 3-3, and 5-5 indicating locations of cross-sectional views depicted in FIGS. 2, 3, and 5 are provided for reference in FIG. 1.

FIG. 2 shows a cross-sectional view of the inverter 100. The inverter 100 in the illustrated example, includes multiple chambers within the housing 132. These chambers include a phase-control chamber 200, a DC chamber 202 (e.g., DC separated chamber), and/or an external communication chamber 204. Partitioning the housing into these chambers enables EMI to be reduced, enabling the inverter to be more compliant with electromagnetic emissions targets. The phase-control chamber 200 contains (e.g., fully encloses) the gate-driver circuit board 114, the AC bus bar assembly 104 depicted in FIG. 1, and partially encloses a control circuit board 310, shown in FIG. 3.

Further, the DC chamber 202 contains the DC bus bar assembly 102 depicted in FIG. 1, and the external communication chamber 204 may contain LV communication components (e.g., a communication circuit board 206, connectors 208, and the like) designed to interface with components external to the inverter. The phase-control chamber 200 may have greater noise than the DC chamber. Additionally, the external communication chamber may have less noise than the DC chamber. In this way, the external communication chamber is designed to protect the LV signals from the noise present in the phase-control chamber.

The DC chamber 202 may be positioned laterally between the phase-control chamber 200 and the external communication chamber 204 (e.g., lower voltage (LV) chamber) and the external communication chamber 204 is positioned on a lateral side 205 of the inverter 100. Partitioning the housing into these chambers enables EMI to be reduced thereby increasing inverter 100 performance. The phase-control chamber 200 contains (e.g., at least partially encloses) the gate-driver circuit board 114 and the AC bus bar assembly 104 depicted in FIG. 1, the DC chamber 202 contains the DC bus bar assembly 102 depicted in FIG. 1, and the external communication chamber 204 may contain external communication components (e.g., the communication circuit board 206, the connectors 208, and the like) designed to interface with components external to the inverter. The phase-control chamber 200 may have a greater amount of EMI than the DC chamber 202. Additionally, the external communication chamber 204 may have less EMI than the DC chamber 202. The different chambers may be demarcated via walls of the housing 132.

FIG. 3 shows a cross-sectional view of the inverter 100 with internal features of the DC bus bar assembly 102 revealed. The AC bus bar assembly 104 and the capacitor 106 are again depicted. The control circuit board 310 is further illustrated in FIG. 3. The control circuit board 310 is designed to alter an amount of electric power distributed from the power electronics unit to the external AC electrical component 108 (e.g., the traction motor).

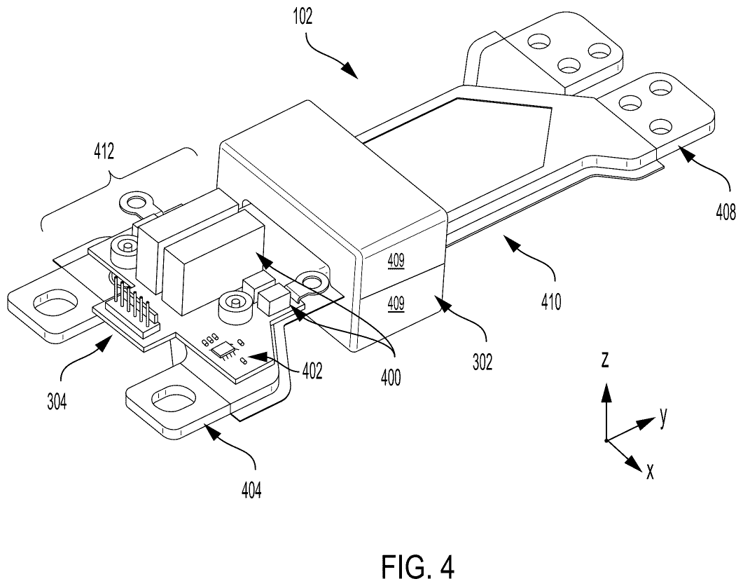

The DC bus bar assembly 102 includes an entry cavity 300 and a choke 302. In some examples, the choke 302 may be a ferrite filter. In other examples, the choke 302 may be formed of a nanocrystalline material or other material, depending on the frequencies to filter. The choke 302 may be formed in multiple sections, in some examples. The construction of the choke is expanded upon herein with regard to FIG. 4.

The entry cavity 300 may contain an EMI PCB assembly 303. In the illustrated example, the EMI PCB assembly 303 includes EMI filtering capacitors 400, a current sensor 402 shown in FIG. 3, and an electrical connector 304 that is designed to electrically connect to the gate-driver circuit board 114, shown in FIG. 1. The DC bus bar assembly 102 is positioned in the DC chamber 202 of the housing 132, as previously discussed. However, in alternate examples, the DC chamber and the external communication chamber may form a single chamber.

As previously indicated, the DC chamber 202 is separated (e.g., isolated) from the other chambers and provide a cleaner zone (with regard to EMI) which contains EMI noise sensitive components such as the DC bus bar assembly 102, the EMI filtering capacitors 400 (described in greater detail herein), and an electrical interface 350 with the capacitor 106.

FIG. 3 further shows one of the DC bus bars 404 and connectors 330 that electrically couple the control circuit board 310 to the DC link capacitor 106. The connectors 330 and the DC bus bars 404 are further described herein. Further, the control circuit board 310 is shown positioned in the phase-control chamber 200.

FIG. 4 shows a detailed view of the DC bus bar assembly 102, with DC bus bars 404 which include holes or other suitable features that enable the DC bus bars to function as an electrical input interface (e.g., bolted electrical input interface) to the DC input connectors 125 as shown in FIG. 1. The DC bus bar assembly 102 further includes output bus bars 408 (e.g., bolted electrical output interface) that is coupled to the capacitor 106, shown in FIG. 1, when assembled. The output bus bars 408 includes tabs with openings to enable a robust electrical connection to be established. The DC bus bars 404 and the other bus bars described herein may be constructed out of a suitable conductive material such as copper, aluminum, brass, combinations thereof, and the like.

In the illustrated example, the choke 302 is included in the DC bus bar assembly 102. The choke 302 is designed to reduce EMI noise exiting the inverter, towards the DC electrical component 110, shown in FIG. 1. Consequently, the inverter may be placed closer to the DC electrical component, if desired. Specifically, in the illustrated example, the choke 302 extends around the body 410 of the assembly at a mid-portion thereof. However, in other examples, the choke may have a different contour (e.g., positioned on an upper or lower side of the body of the bus bar assembly) and/or may be placed in a different location along the bus bar assembly. In the illustrated example, the body 410, the bus bars 404, and the bus bars 408 form a continuous shape. However, other bus bar assembly configurations may be used, in other examples.

The choke 302 may be constructed with different choke sections 409. These sections may specifically include an upper section and a lower section that when brought together surround the body 410 of the DC bus bar assembly 102. Designing the choke in multiple sections allows the DC bus bar assembly to be more efficiently constructed. The choke sections 409 may have a C-type shape to enable the filter to contour to the bus bar body 410, thereby increasing the DC bus bar assembly's space efficiency.

The choke 302 may specifically be a common-mode filter which selectively removes noise in a targeted frequency range while allowing signals in another frequency to pass, in one example. In this way, the DC bus bar assembly may precisely filter out undesirable noise.

The DC bus bar assembly 102 further includes an EMI filtering and current sensing circuit board 412. In the illustrated example, the EMI filtering and current sensing circuit board 412 includes the EMI filtering capacitors 400, the current sensor 402 (e.g., Hall effect sensor), and the connector 304 (e.g., the signal harness). The current sensor 402 reads the DC current flowing through the DC bus bars 404. The connector 304 sends signals to the control circuit board 310, shown in FIG. 3. Wires may be used to send the signals between the connector 304 and the control circuit board 310. The EMI filtering capacitors 400 decrease the amount of EMI noise coming out of the inverter towards the external DC electrical component 110 (towards the vehicle high-voltage power distribution system).

The EMI filtering and current sensing circuit board 412 with the sensing and filtering components may be positioned between the DC bus bars 404 and the choke 302, in relation to the y-axis. In this way, the circuitry on the board may be protected from EMI, thereby increasing inverter performance in comparison to inverters without the EMI filtering features described herein.

Further, positioning the EMI filtering and current sensing circuit board 412 near the DC input connectors 125, shown in FIG. 1, allows the current sensor to have closer proximity to the DC bus bars 404 than other locations such as near the rear of the DC bus bar assembly 102. In this way, the current sensor reading may be simplified which enable the signal to be processed using less processing resources, if wanted.

It will also be appreciated that a field concentrator may be omitted from the inverter due to the placement of the EMI filtering and current sensing circuit board 412 near the input connectors 125, shown in FIG. 1 (e.g., near the front of the DC bus bar assembly 102), if wanted. When the field concentrator is omitted, the DC current sensor signal may be filtered and compensated to remove the AC components from the signal. The DC current signal processing may contain one or more of the following processing strategies: offset calibration; gain calibration; low-pass filtering; and external field cancellation (e.g., the removal of influence from nearby conductors such as the phase bus bars).

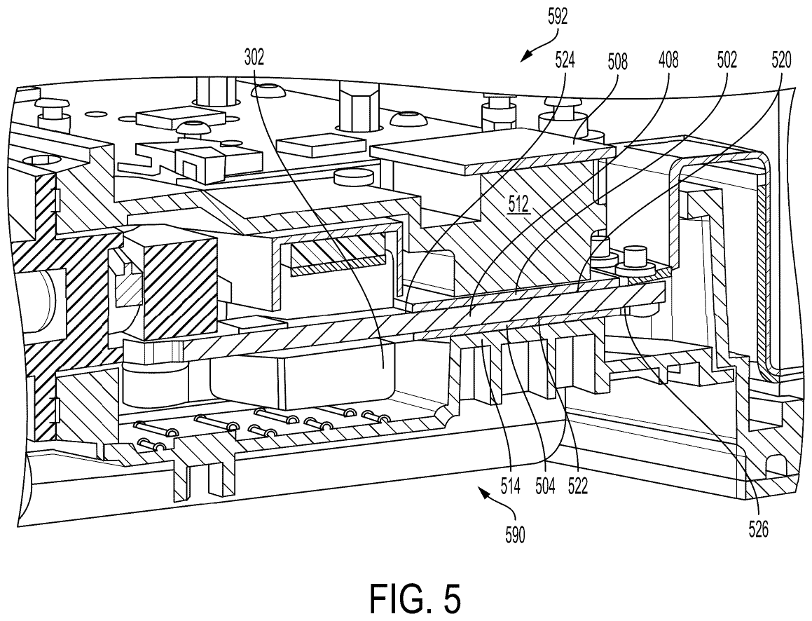

FIG. 5 shows a cross-sectional view of the DC bus bar assembly 102. As described above, the DC bus bar assembly 102 may comprise one or more DC bus bars, including DC bus bar 408, as shown in FIG. 5. The DC bus bar assembly 102 may be cooled via a system of thermal pads.

The DC bus bar 408 may be surrounded by a first thermal pad 502 and a second thermal pad 504 such that the DC bus bar 408 is positioned between the first and second thermal pads 502, 504. In some examples, the first thermal pad 502 may be positioned in face sharing contact with a first flat surface 520 of the DC bus bar 408. The first flat surface 520 may be proximate to the DC input connector (e.g., the DC input connector 125 of FIG. 1). In other examples, a first insulation paper 524 may be positioned between the first thermal pad 502 and the first flat surface 520 of the DC bus bar 408. For example the first thermal pad 502 may be in face sharing contact with the first insulation paper 524 on a first side 590 and the DC bus bar 408 may be in face sharing contact with the first insulation paper 524 on a second opposing side 592.

Similarly, in some examples, the second thermal pad 504 may be positioned in face sharing contact with a second flat surface 522 of the DC bus bar 408. The second flat surface 522 may be opposite the first flat surface 520. In other examples, a second insulation paper 526 may be positioned between the second thermal pad 504 and the second flat surface 522 of the DC bus bar 408. For example, the second thermal pad 504 may be in face sharing contact with the second insulation paper 526 at the second side 592 and the DC bus bar 408 may be in face sharing contact with the second insulation paper 526 at the first opposing side 590. Thus, the second thermal pad 504 may be positioned towards the first side 590 of the DC bus bar 408 and the first thermal pad 502 may be positioned towards the second side 592 of the DC bus bar 408. The first and second insulation papers may be configured to safeguard the components to reduce conductivity, thus increasing durability and reliability.

The first and second thermal pads 502, 504 may be compressible thermal pads. For example, the thermal pads may be formed of a compressible material that is flexible for various end use applications as the thermal pads may compress and form different thicknesses between other components of the inverter 100. As an example, the compressible thermal pads may have 25% compressibility to maintain thermal efficiency. In this way, the necessary preciseness of forming the thermal pads and other components may be reduced, providing for an easier manufacturing process.

The first thermal pad 502 may further be in face sharing contact with a first section 512 of the housing 132. The first section 512 may be a portion of the main casing of the inverter, in some examples. The first section 512 of the housing may function as a heat exchanger to dissipate heat generated through the DC bus bar 408. The first thermal pad 502 may be in contact with the first section 512 on an opposite side of the thermal pad to the side that is in contact with the bus bar. The first thermal pad 502 may be affixed to one or both of the first section 512 and the DC bus bar 408 via an adhesive. For example, the adhesive may be applied to one side of the thermal pad and via the adhesive and pressure from components of the assembly may maintain the position of the thermal pad.

Similarly, the second thermal pad 504 may be in face sharing contact with a second section 514 of the housing 132. The second section 514 of the housing may be a cover configured to close the DC chamber. The second section 514, like the first section 512, may function as a heat exchanger to dissipate heat generated through the DC bus bar 408. The second section 514 of the housing may be positioned on an opposite side of the second thermal pad 504 to the DC bus bar 408. Thus, the DC bus bar 408 may be surrounded by the first and second thermal pads 502, 504, which may be surrounded by the first and second sections 512, 514 of the housing. In this way, the DC bus bar 408 may be positioned within the housing and may be electrically isolated from the housing, by way of the thermal pads. The two thermal pads surrounding the DC bus bar 408 may provide additional surface area for cooling and heat dissipation, thereby increasing the thermal exchange between the housing and the bus bar. Additionally, the thermal pads may electrically isolate the DC bus bar from the case.

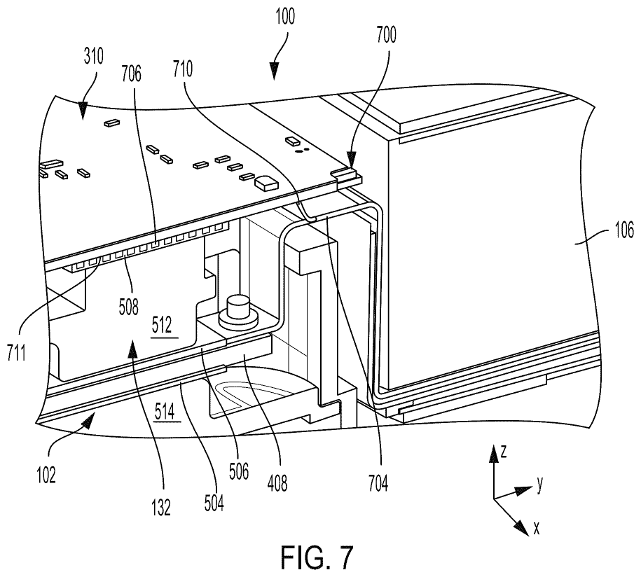

In some examples, a third compressible thermal pad 508 may be included in the inverter 100. The third thermal pad 508 may be positioned on an opposite side of the first section 512 of the housing 132 from the first thermal pad 502. For example, the first thermal pad 502 may be positioned in thermal contact with the first side 590 of the first section 512 and the third thermal pad 508 may be positioned in thermal contact with the second side 592 of the first section 512. The third thermal pad 508 is further described with respect to FIG. 7 below. The third thermal pad 508 may be configured to cool the capacitor passive discharge, in some examples.

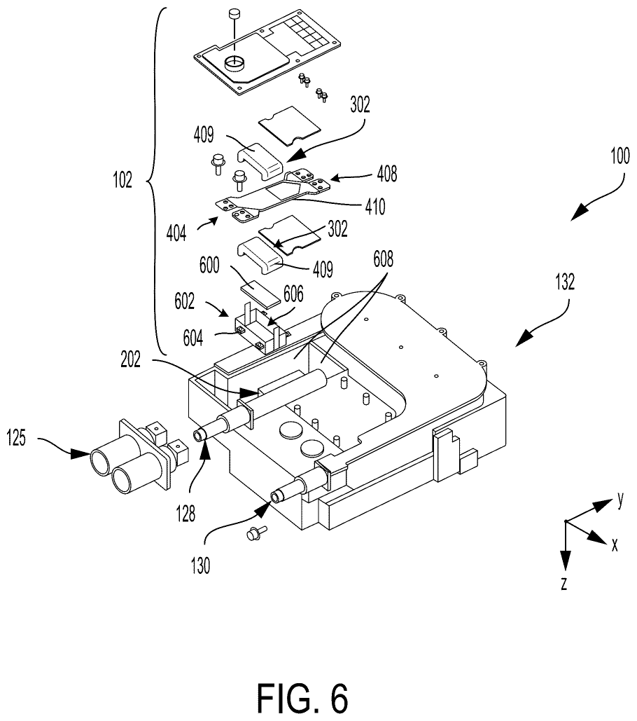

FIG. 6 shows the inverter 100 with the housing 132 and the DC bus bar assembly 102 in an exploded view. The DC bus bar assembly 102 includes the DC bus bars 404 formed on a conductive plate and the choke 302 which may be at least partially surround the conductive plate and reduce the amount of EMI noise that exits the DC chamber. In this way, the likelihood of the inverter undesirably electromagnetically interfering with surrounding components is decreased. The DC input connectors 125 and the coolant inlet 128 and the coolant outlet 130 are again shown in FIG. 6.

The choke 302 may be constructed in multiple sections 409 (e.g., an upper and lower section), as shown in the illustrated example. When assembled, the sections 409 surround the body 410 of the DC bus bars 404 and 408.

To reduce vibration transmission to the bus bar assembly 102, a compliant pad 600 and in some examples, a support structure 602 (e.g., a polymer support) may be used to attach the bus bar assembly to the housing 132. The compliant pad 600 may be constructed out of polymer foam to enable vibration attenuation. To elaborate, the compliant pad 600 reduces movement of the choke 302 to reduce choke vibration to the bus bar body 410. Constraining the movement of the choke 302 reduces the change of the choke degrading (e.g., piercing) the electrical insulation materials that may be applied on and around the bus bar. Further, an adhesive material, such as a glue, may be positioned between the choke 302 and the DC bus bars 404 to reduce movement of the choke 302.

Further, the support structure 602 may be constructed out of a polymer to avoid an undesirable electrical connection between the housing 132 and the DC bus bar assembly 102. The support structure 602 holds the choke 302 around the bus bar body 410. Further, the support structure 602 holds may compress the choke 302 to further reduce the likelihood of choke vibration. To elaborate, to achieve a targeted amount of filter compression of the support structure 602, the threading engagement between the attachment devices and the housing may be adjusted. However, other techniques for augmenting filter compression have been contemplated.

Further, the support structure 602 may include attachment interfaces 604 that are designed to receive attachment devices (e.g., screws, bolts, combinations thereof, and the like) for attachment to the housing. In the illustrated example, the support structure 602 includes a recess 606 that is sized to receive the compliant pad 600 and at least a portion of the choke 302. The recess 606 may have a rectangular shape in cross-section to enable the pad and the filter to be efficiently mated therewith, in one example. However, other contours of the support structure recess may be used in alternate examples. Using a support structure and compliant pad with the abovementioned features increases the space efficiency of the inverter while providing a desired filtering functionality.

FIG. 6 further shows walls 608 of the housing 132 that may demarcate the DC chamber 202. The walls 608 may each extend in a vertical direction. Further, one of the walls may extend in a longitudinal direction and another wall may extend in a lateral direction. In this way, the DC chamber may be contoured to enclose the DC bus bar assembly in a space efficient manner. However, other DC chamber contours have been contemplated.

FIG. 7 shows a section of the inverter 100. The inverter 100 depicted in FIG. 7 has a current sensor 700 positioned on the control circuit board 310 as opposed to the EMI filtering and current sensing circuit board. The current sensor 700 generates a current reading of the current flowing through a bus bar 704 which electrically couples the DC bus bars 408 to the capacitor 106. Field concentrators may also be forgone in the inverter 100, to simplify inverter construction and increase the inverter's space efficiency.

Positioning the current sensor 700 on the control circuit board 310 may allow the signal path to the microprocessor (which may also be placed on the control circuit board) to be reduced, if desired. Further, positioning the current sensor 700 on the control circuit board 310 also allows the use of a connector and harness system in the signal path to be avoided, if so desired.

FIG. 7 further shows discharge resistors 706 coupled to the control circuit board 310. In the illustrated example, the discharge resistors 706 are coupled to the control circuit board 310 and the third thermal pad 508. To elaborate, the discharge resistor 706 may be in thermal contact with the housing 132 by way of the third thermal pad 508. The discharge resistors 706 may be positioned in recesses in the third thermal pad 508 to increase the amount of heat transferred from the resistors to the housing 132. Sections of the third thermal pad 508 between the recesses may be in contact with a lower surface 711 of the control circuit board 310. The discharge resistor 706 discharges the DC link capacitor 106 when the inverter assembly is turned off. The discharge functionality of the resistor 706 may be passively implemented without any control inputs.

FIG. 7 further shows an electrical spring connector 710 that provides electrical connection between the control circuit board 310 and the bus bar 704. The electrical spring connector 710 may be used in addition to or as an alternative to the connectors 330, shown in FIG. 3.

The third thermal pad 508 may be coupled to the lower surface 711 of the control circuit board 310 and the first section 512 of the housing 132 that is coupled to the DC bus bar assembly 102. Thus, the first section 512 of the housing 132 may be a common cooling surface between the discharge resistor and the DC bus bar. Designing the inverter with the resistors 706 and the third thermal pad 508 allows the space efficiency of the inverter to be increased and further enables the number of circuit boards in the inverter to be reduced, if desired.

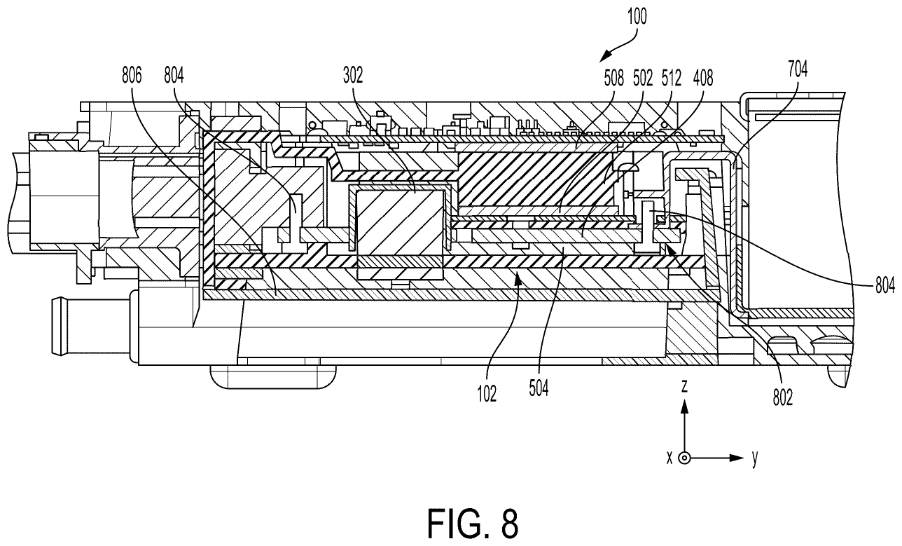

Turning now to FIG. 8, the DC bus bar assembly 102 is again shown in a cross-sectional view. As described above, the DC bus bar assembly 102 comprises the DC bus bar 404 and the DC bus bar 408. The DC bus bar 408 may be cooled via the first and second thermal pads 502, 504. The first section 512 of the housing 132 may be a common cooling surface between the discharge resistor (e.g., resistors 706) and the DC bus bar 408.

As is shown in FIG. 8, the first section 512 of the housing 132 may be positioned vertically above the DC bus bar 408 and the second section 514 of the housing 132 may be positioned vertically below the DC bus bar 408. As such, the thermal pads therebetween (e.g., the first compressible thermal pad between the DC bus bar 408 and the first section 512 and the second compressible thermal pad between the DC bus bar 408 and the second section 514) may surround the DC bus bar on both the top and bottom, increasing the surface area for thermal exchange with the case.

The DC bus bar 408 may comprise one or more passage openings 802 through which a fastener 804 may be placed through. The fastener 804 may be passed through the passage openings 802 towards the thermal interface material (e.g., the thermal pads).

FIG. 8 further shows a closing cover 806 of the housing 132. The closing cover 806 may be formed as part of or be otherwise coupled with the first section 512 of the housing 132. The closing cover 806 may extend around and under the choke 302 and under the DC bus bar 408 as well. With this arrangement, the DC bus bar assembly 102 may have reduced EMI.

The disclosure also provides support for an inverter, comprising: a case, a direct current (DC) bus bar positioned within the case and electrically isolated from the case, a first compressible thermal pad positioned on a first flat surface of the DC bus bar proximate to a DC input connector, and a second compressible thermal pad positioned on a second flat surface of the DC bus bar opposite the first flat surface. In a first example of the system, the first compressible thermal pad is in thermal contact with a first section of the case. In a second example of the system, optionally including the first example, the first section of the case is configured as a heat exchanger. In a third example of the system, optionally including one or both of the first and second examples, the first section of the case is configured as a common cooling surface between a discharge resistor and the DC bus bar. In a fourth example of the system, optionally including one or more or each of the first through third examples, the system further comprises: a third compressible thermal pad positioned in thermal contact with the first section of the case and the discharge resistor, wherein the first compressible thermal pad is positioned on a first side of the first section of the case and the third compressible thermal pad is positioned on a second side of the first section of the case. In a fifth example of the system, optionally including one or more or each of the first through fourth examples, the system further comprises: a first insulation paper positioned between the first compressible thermal pad and the first flat surface of the DC bus bar. In a sixth example of the system, optionally including one or more or each of the first through fifth examples, the system further comprises: a second insulation paper positioned between the second compressible thermal pad and the second flat surface of the DC bus bar. In a seventh example of the system, optionally including one or more or each of the first through sixth examples, the second compressible thermal pad is in thermal contact with a second section of the case. In a eighth example of the system, optionally including one or more or each of the first through seventh examples, the first and second compressible thermal pads are configured for thermal exchange of heat from the DC bus bar to the case.

The disclosure also provides support for a cooling system for a direct current (DC) bus bar of an inverter, comprising: a first thermal pad positioned on a first side of the DC bus bar, and a second thermal pad positioned on a second, opposing side of the DC bus bar, wherein the first and second thermal pads are in thermal contact with the DC bus bar and with a case of the inverter. In a first example of the system, the first and second thermal pads are formed of a compressible material. In a second example of the system, optionally including the first example, the first thermal pad is in thermal contact with a first section of the case, wherein the first section of the case is positioned vertically above the DC bus bar. In a third example of the system, optionally including one or both of the first and second examples, the system further comprises: a third thermal pad in thermal contact with the case of the inverter, wherein the third thermal pad comprises recesses configured to contact a discharge resistor. In a fourth example of the system, optionally including one or more or each of the first through third examples, the first section of the case is configured as a heat exchanger between the third thermal pad and the first thermal pad. In a fifth example of the system, optionally including one or more or each of the first through fourth examples, the first section of the case is configured as a common cooling surface between the discharge resistor and the DC bus bar. In a sixth example of the system, optionally including one or more or each of the first through fifth examples, the second thermal pad is in thermal contact with a second section of the case, wherein the second section of the case is positioned vertically below the DC bus bar. In a seventh example of the system, optionally including one or more or each of the first through sixth examples, a first insulation paper is positioned between the first thermal pad and the DC bus bar and a second insulation paper is positioned between the second thermal pad and the DC bus bar.

The disclosure also provides support for a power electronics unit for a traction motor, comprising: a direct current (DC) chamber including: a DC bus bar assembly comprising at least one DC bus bar, wherein the DC bus bar is positioned between and in thermal contact with a first compressible thermal pad and a second compressible thermal pad. In a first example of the system, the DC bus bar assembly is electrically isolated from a housing of the power electronics unit via the first and second compressible thermal pads. In a second example of the system, optionally including the first example, the first compressible thermal pad is in thermal contact with a first section of the housing that is positioned vertically above the DC bus bar and the second compressible thermal pad is in thermal contact with a second section of the housing that is positioned vertically below the DC bus bar.

FIGS. 1-8 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. An inverter, comprising:
a case;
a direct current (DC) bus bar positioned within the case and electrically isolated from the case;
a first compressible thermal pad positioned on a first flat surface of the DC bus bar proximate to a DC input connector; and
a second compressible thermal pad positioned on a second flat surface of the DC bus bar opposite the first flat surface.

2. The inverter of claim 1, wherein the first compressible thermal pad is in thermal contact with a first section of the case.

3. The inverter of claim 2, wherein the first section of the case is configured as a heat exchanger.

4. The inverter of claim 2, wherein the first section of the case is configured as a common cooling surface between a discharge resistor and the DC bus bar.

5. The inverter of claim 4, further comprising a third compressible thermal pad positioned in thermal contact with the first section of the case and the discharge resistor, wherein the first compressible thermal pad is positioned on a first side of the first section of the case and the third compressible thermal pad is positioned on a second side of the first section of the case.

6. The inverter of claim 1, further comprising a first insulation paper positioned between the first compressible thermal pad and the first flat surface of the DC bus bar.

7. The inverter of claim 1, further comprising a second insulation paper positioned between the second compressible thermal pad and the second flat surface of the DC bus bar.

8. The inverter of claim 1, wherein the second compressible thermal pad is in thermal contact with a second section of the case.

9. The inverter of claim 1, wherein the first and second compressible thermal pads are configured for thermal exchange of heat from the DC bus bar to the case.

10. A cooling system for a direct current (DC) bus bar of an inverter, comprising:
a first thermal pad positioned on a first side of the DC bus bar; and
a second thermal pad positioned on a second, opposing side of the DC bus bar, wherein the first and second thermal pads are in thermal contact with the DC bus bar and with a case of the inverter.

11. The cooling system of claim 10, wherein the first and second thermal pads are formed of a compressible material.

12. The cooling system of claim 10, wherein the first thermal pad is in thermal contact with a first section of the case, wherein the first section of the case is positioned vertically above the DC bus bar.

13. The cooling system of claim 12, further comprising a third thermal pad in thermal contact with the case of the inverter, wherein the third thermal pad comprises recesses configured to contact a discharge resistor.

14. The cooling system of claim 13, wherein the first section of the case is configured as a heat exchanger between the third thermal pad and the first thermal pad.

15. The cooling system of claim 13, wherein the first section of the case is configured as a common cooling surface between the discharge resistor and the DC bus bar.

16. The cooling system of claim 10, wherein the second thermal pad is in thermal contact with a second section of the case, wherein the second section of the case is positioned vertically below the DC bus bar.

17. The cooling system of claim 10, wherein a first insulation paper is positioned between the first thermal pad and the DC bus bar and a second insulation paper is positioned between the second thermal pad and the DC bus bar.

18. A power electronics unit for a traction motor, comprising:
a direct current (DC) chamber including:
a DC bus bar assembly comprising at least one DC bus bar, wherein the DC bus bar is positioned between and in thermal contact with a first compressible thermal pad and a second compressible thermal pad.

19. The power electronics unit of claim 18, wherein the DC bus bar assembly is electrically isolated from a housing of the power electronics unit via the first and second compressible thermal pads.

20. The power electronics unit of claim 19, wherein the first compressible thermal pad is in thermal contact with a first section of the housing that is positioned vertically above the DC bus bar and the second compressible thermal pad is in thermal contact with a second section of the housing that is positioned vertically below the DC bus bar.
